(19) United States
(12) Patent Application Publication
(10) Pub. No.: US 2026/0064917 A1
(43) Pub. Date: Mar. 5, 2026

(54) INVERSE MODELLING AND TRANSFER LEARNING SYSTEM IN AUTONOMOUS VEHICLE VIRTUAL TESTING

(71) Applicant: Siemens Industry Software NV, Leuven (BE)

(72) Inventors: Wei Xia, Raritan, NJ (US); Elena Arvanitis, Somerville, NJ (US); Scott Kolb, Hopewell, NJ (US); Lucia Mirabella, Plainsboro, NJ (US); Albert Anderson, Muskego, WI (US); Yashesh Deepakkumar Dhebar, East Lansing, MI (US); Ioana Nikova, Heverlee (BE); Edwin van Hassel, XE Mierlo (NL)

(73) Assignee: Siemens Industry Software NV, Leuven (BE)

(21) Appl. No.: 19/106,379

(22) PCT Filed: Aug. 26, 2022
(86) PCT No.: PCT/US2022/041677

§ 371 Date: Feb. 25, 2025

(51) Int. Cl. G06F 30/27; G06N 3/096

(52) U.S. Cl. CPC G06F 30/27; G06N 3/096

(57) ABSTRACT

A computer-implemented method of engineering design includes performing a simulation for a design under test of the design interacting in a real-world environment, in a computer processor, generating simulation data from performance of the simulation, storing the generated simulation data in a computer memory, extracting the generated simulation data to train a first inverse model neural network, and generating a plurality of design parameters from the inverse model neural network. A visualization representative of the generated plurality of design parameters for display to a user allows an expert user to evaluate the suggested design parameters and select some or all of the suggested design parameters. For existing designs more data is available for the simulation than for a new design. The inverse model for a new design may be augmented by transferring stored knowledge in a pre-existing inverse model to the model for the new design.

### TECHNICAL FIELD

This disclosure relates to autonomous vehicle design and engineering.

### BACKGROUND

Autonomous vehicles (AV) have recently garnered considerable interest as advancements in robotics, artificial intelligence (AI), computer vision, and simulation have developed. These cutting-edge technologies have enabled success in AV technologies. While much testing of AV implementations has occurred, early testing in real-world conditions have resulted in accidents endangering human life and threatening public safety.

Broad rollout and acceptance of AVs is further limited by varying regulatory requirements in different regions. Due to these constraints, there is a recognized need for comprehensive testing in a simulated environment to fully understand an AV's basic operating patterns and to train an AI model to control it.

Simulation is only as accurate as the precision of the models allow. To build realistic scenarios, different vehicle configurations, and interactions between the two requires significant effort on the part of simulation engineers to build a scenario of interest and to insert a specific vehicle model into the scenario. Additionally, simulations can be very slow due to the complexity of the real-world conditions they seek to replicate. The time demands placed on simulation design often result in limited exploration of the design space of an AV and frustrate the achievement of safe and efficient AVs.

### SUMMARY

A computer-implemented method of engineering design includes performing a simulation for a design under test of the design interacting in a real-world environment, in a computer processor, generating simulation data from performance of the simulation, storing the generated simulation data in a computer memory, extracting the generated simulation data to train a first inverse model neural network, and generating a plurality of design parameters from the inverse model neural network. A visualization representative of the generated plurality of design parameters for display to a user allows an expert user to evaluate the suggest design parameters and select some or all of the suggest design parameters. For existing designs more data is available for the simulation than for a new design. The inverse model for a new design may be augmented by transferring stored knowledge in a pre-existing inverse model to the model for the new design.

The visualization representing the plurality of design parameters generated by the inverse model may be provides as a 3D scatter plot, a 2D scatter plot or contour plot. For higher dimensional design spaces, a parallel or embedded plot may be used. The visualization may be presented to a user for further review and analysis of the suggested design parameters. Design parameters selected from the generated design parameters may be provided to the method for further testing or simulation.

For new designs, existing stored knowledge contained in a pre-existing inverse model neural network may be transferred to a new inverse model neural network. This may be accomplished by directly transferring some of the neural network layers of the new inverse model along with the associated weights. This will augment the new inverse model and improve performance for new designs where less simulation data is available to the inverse model neural network.

According to some embodiments, the design under test is a design for an autonomous vehicle. The design parameters may correspond to control functions of the autonomous vehicle or may include environmental scenarios in which the autonomous vehicle operates.

The inverse model receives a safety metric as input and generates a set of design parameters that are predicted to comply with the safety metric. The design parameters may be sampled using a conditional distribution based on a safety metric input being considered. For multi-modal distributions, a mixture density network may be applied to the conditional distribution.

According to a system for exploring an engineering design space a computer processor is in communication with a non-transitory computer memory storing instructions that when executed by the computer processor cause the computer processor to

perform a simulation for a design under test interacting in a real-world environment, generate simulation data from performance of the simulation, store the generated simulation data in a computer memory, extract the generated simulation data to train a first inverse model neural network, and generate a plurality of design parameters from the inverse model neural network. The computer processor may further execute instructions to generate a visualization representative of the generated plurality of design parameters. According to some embodiments, the computer processor may execute further instructions to insert stored knowledge from a pre-existing inverse model neural network to a new inverse model neural network associated with a new design. The represented knowledge from the previously trained inverse model neural network may be transferred by copying one or more layers of the previously trained inverse model neural network including weights of the layers into the new inverse model neural network. Systems according to this disclosure may be related to design of an autonomous vehicle.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 illustrates an architecture for inverse design for design space exploration for design of AVs according to aspects of embodiments described in this disclosure.

FIG. 2 is an illustration of the use of a mixture density network for a multi-modal distribution of design parameters according to embodiments of this disclosure.

FIG. 3 is a process flow diagram for a method of generating design parameters for an AV control system according to embodiments of this disclosure.

FIG. 4 is a block diagram of a computer system that may be used for practicing methods and building systems of embodiments for exploring a design space described in this disclosure.

### DETAILED DESCRIPTION

Testing of AV designs presents several challenges. Presently, virtual testing of AV designs focuses on building physics tools in a simulation application to test the AV design in varying scenarios. An AI forward model is conventionally used to estimate responses to the AV design parameters and control strategies under various scenarios. To explore the vast design space for control systems in real-world conditions while complying with specific key performance indicators (KPI) or safety metrics, techniques such as evolutionary optimization algorithms or reinforcement learning may be used.

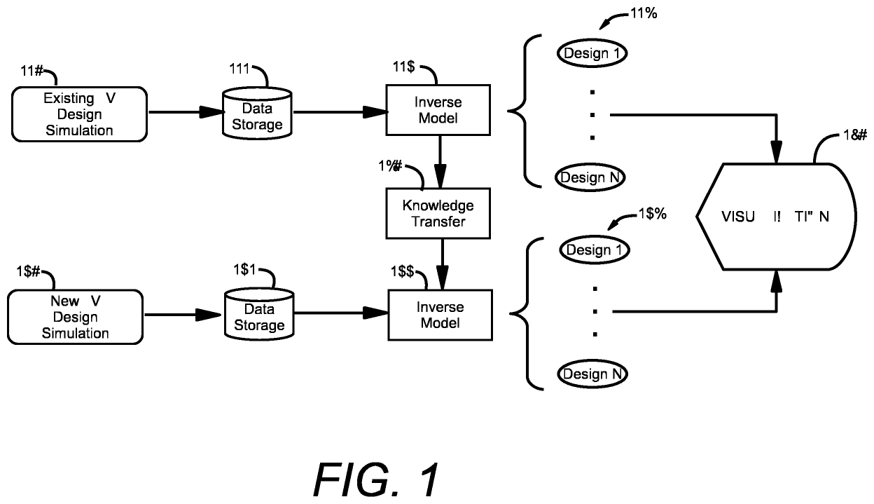

FIG. 1 illustrates an architecture for inverse design enabling efficient design space exploration according to aspects of embodiments described in this disclosure.

When considering an AV simulation, the simulation may be viewed using existing AV designs 110 or it may use new designs that have not been tested before 120. An AV simulation module 110, 120 simulates the AV design across different conditions. For example, in an exemplary embodiment, a check may be performed to determine if a collision would occur if a pedestrian steps into the path of the AV. There may be different testing scenarios for different vehicles. The simulator may be set up using a commercially available physics-based simulation platform, such as those used in the automobile industry. These systems may be utilized to develop advanced driver assistance systems (ADAS), which may be based on sensor data. For an existing design 110 it may be assumed that there are more design parameters that may be estimated than for a new design 120. In the case of a new design 120, the simulation may be performed using less simulated data.

Data will be generated during simulation, and the data generated may be stored in a data store 111, 121. Using commercially available software, the simulation data may be captured and stored. In an embodiment, the data may be saved in the data store 111, 121 as a comma separated value (csv) file format. In that example, the csv file may be stored in an SQL database for query and retrieval later in the process.

The data store 111, 121 provides input to an inverse model module neural network, 112, 122. The inverse model module neural network 112, 122 retrieves the data stored in the data store 111, 121 and uses the retrieved data to train a generative model. The generative model is designed to map a safety metric to a set of possible design parameters to achieve the target safety metric. Conventionally, forward neural networks, which seek to map many design parameters to one safety metric (e.g., a many-to-one relationship). These conventional techniques do not fit a one-to-many relationship as required here.

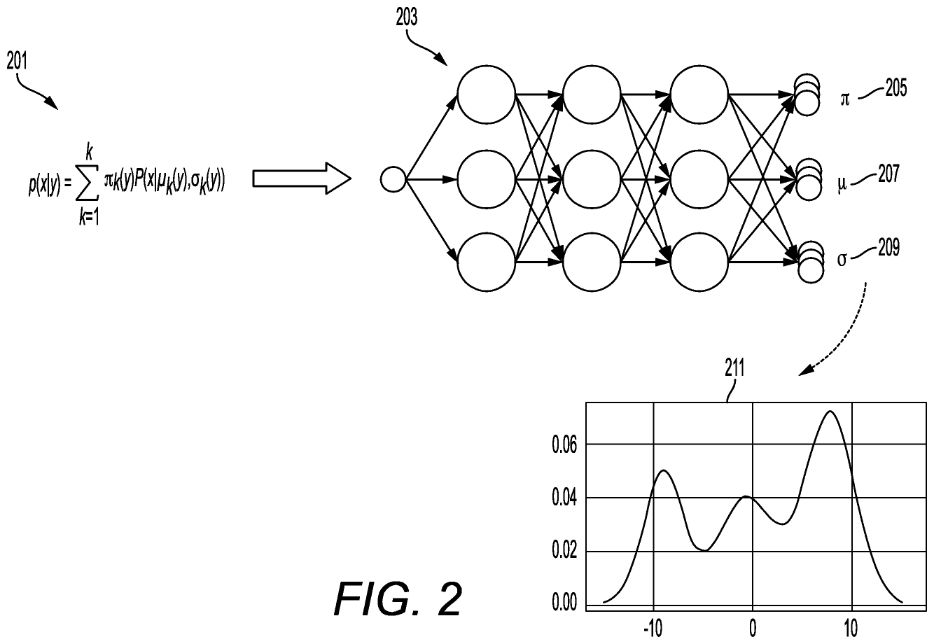

According to embodiments of this disclosure, this poor performance is mitigated by estimating a conditional distribution problem. A set of design parameters may be denoted as x and the safety metric designated as y. The conditional distribution p(x|y) may be approximated. Thus, for one specific y the conditional distribution provides multiple design parameters by sampling from the conditional distribution. The conditional distribution may exist in multiple forms. Most frequently, the conditional distribution will be multi-modal. According to an embodiment, when the conditional distribution is multi-modal, a mixture density network is used to approximate the distribution. The mixture density network is shown in FIG. 2. For other types of design parameters, other techniques may be considered. For example, if the design parameters are continuous, a Gaussian distribution may be used. In another example, the design parameters contain discrete values a discretized logistic distribution may be used.

For a new design, a new AV design simulation is performed 120 and data generated from the simulation 120 is stored in data store 121. As discussed above, it is expected that for a new design, there are less design parameters available for the simulation 120. To improve the efficiency of generating design parameters and to leverage previous knowledge, a knowledge transfer module 130 transfers knowledge from an existing inverse model neural network 112 and insert that knowledge into the new design inverse model neural network 122. The knowledge transfer module 130 works to transfer knowledge from a well-trained inverse model to a new scenario based on fewer data points. According to an embodiment, some of the layers in the well-trained inverse model 120 are directly inserted along with their weights into the new inverse model 122. The original smaller amount of data generated by the new simulation 120 may be used to fine tune the inverse model 122, which now contains the trained layers from the pre-existing inverse model 112.

The inverse model uses the data from data store 111, 121 to train the inverse model neural network 112, 122 and maps a safety metric to data parameters 113, 123 that are predicted to comply with the safety metric. When the inverse model makes a successful prediction 112, 122 the resulting design parameters 113, 123 may be used in simulation, and it should be expected that the original safety metric will be observed using the newly generated design parameters 113, 123.

In a final phase of the architecture, the design parameters are displayed in a visualization module 140. The visualization module 140 provides a direct visualization of the inverse model 113, 123. This may be achieved through sampling some of the data points from the inverse model 113, 123 and using available graphical tools to plot the selected samples. If the design parameters are two dimensional or three dimensional, a scatter plat may be used to provide a direct visualization of these parameters. In cases of higher dimensional parameter spaces, the results may be visualized in other manners, such as parallel plots providing both parallel and radial views. Embedding may be utilized to embed higher dimensional data into lower dimensional space enabling simpler and more convenient visualization.

Visualization module 140 provides a simplified perspective of potential solutions generated by the inverse models 112, 122. These simplified views may be easily viewed and analyzed by a design professional and the expert knowledge possessed by the individual may be applied to select certain suggested design parameters. The expert may be aware of other dependencies or constraints that may qualify or disqualify the design parameters 113, 123 provided by the inverse models 112, 122. Accordingly, methods and systems according to the embodiments of this disclosure allow for a more thorough exploration of the design space, which is unachievable through manual processes of testing design alternatives one at a time.

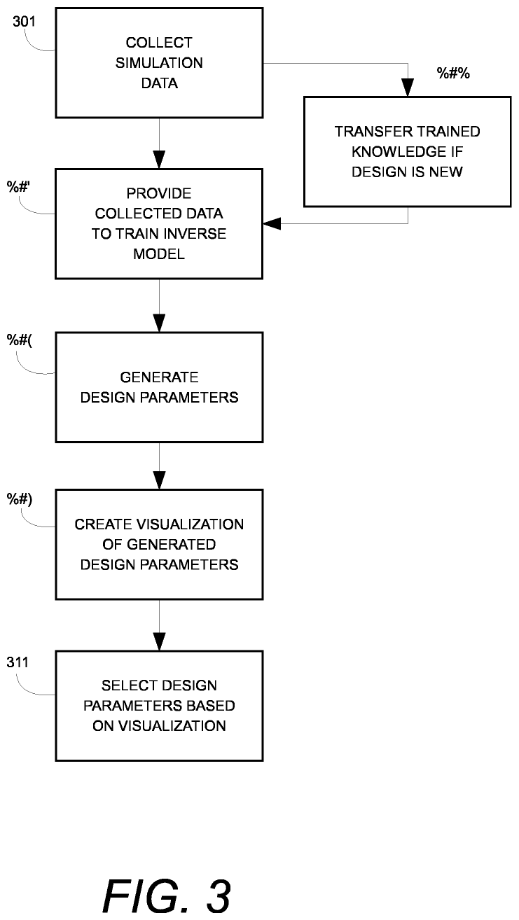

FIG. 3 is a process flow diagram for exploring the design space for a design according to embodiments of this disclosure. The design may be an existing design or a new design that has not been previously simulated. A simulation is run on the proposed design. During the simulation data is generated and collected 301. The collected data is stored in a data store. From the data store, the data from the simulation is retrieved and used to train a neural network for generating an inverse model 305. If the design under consideration is a new design, the neural network for the inverse model may be augmented using previously trained knowledge from an already existing design 303. The existing knowledge may be taken from the previously trained inverse model by directly moving layers of the existing inverse model along with their weights and directly inserting them into the new design's inverse model neural network.

The inverse model network takes a safety metric as an input and predicts a set of design parameters that will result in compliance with the safety metric 307. When the inverse model neural network has generated the set of design parameters 307, a visualization module takes the information about the generated set of parameters and creates a visualization of the generated data. The information may be displayed in the form of a scatter plot, or for high dimensional parameter spaces, the information may be displayed as parallel plots in either or both of a parallel view and a radial view. Embedding techniques may also be employed to embed higher dimensional space in to lower dimensional space to enable easy and convenient visualization. A design expert may be provided with the visualization and analyze or review the suggested set of design parameters and decide on their applicability in the current design. Based on the information presented in the visualization, the subject matter expert may select some or all of the suggested parameters for use in a design 311.

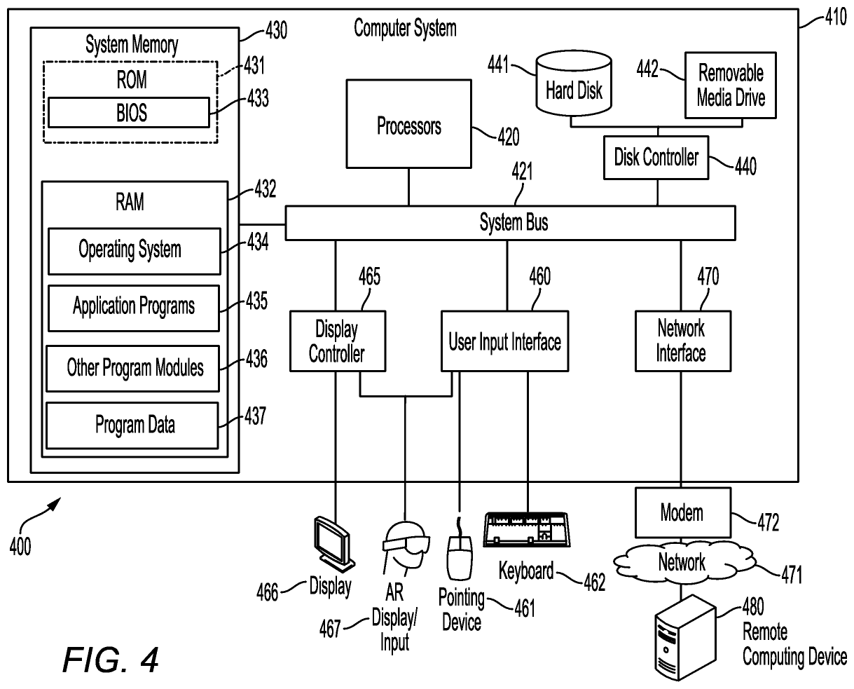

FIG. 4 illustrates an exemplary computing environment 400 within which embodiments of the invention may be implemented. Computers and computing environments, such as computer system 410 and computing environment 400, are known to those of skill in the art and thus are described briefly here.

As shown in FIG. 4, the computer system 410 may include a communication mechanism such as a system bus 421 or other communication mechanism for communicating information within the computer system 410. The computer system 410 further includes one or more processors 420 coupled with the system bus 421 for processing the information.

The processors 420 may include one or more central processing units (CPUs), graphical processing units (GPUs), or any other processor known in the art. More generally, a processor as used herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting, or transmitting information for use by an executable procedure or an information device, and/or by routing the information to an output device. A processor may use or comprise the capabilities of a computer, controller, or microprocessor, for example, and be conditioned using executable instructions to perform special purpose functions not performed by a general-purpose computer. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device. The computer environment may be cloud-based, with processors and memory running on servers in remote locations. Cloud processing may produce data that is transferred locally to effect or interact with computing resources that are locally situated.

Continuing with reference to FIG. 4, the computer system 410 also includes a system memory 430 coupled to the system bus 421 for storing information and instructions to be executed by processors 420. The system memory 430 may include computer readable storage media in the form of volatile and/or nonvolatile memory, such as read only memory (ROM) 431 and/or random-access memory (RAM) 432. The RAM 432 may include other dynamic storage device(s) (e.g., dynamic RAM, static RAM, and synchronous DRAM). The ROM 431 may include other static storage device(s) (e.g., programmable ROM, erasable PROM, and electrically erasable PROM). In addition, the system memory 430 may be used for storing temporary variables or other intermediate information during the execution of instructions by the processors 420. A basic input/output system 433 (BIOS) containing the basic routines that help to transfer information between elements within computer system 410, such as during start-up, may be stored in the ROM 431. RAM 432 may contain data and/or program modules that are immediately accessible to and/or presently being operated on by the processors 420. System memory 430 may additionally include, for example, operating system 434, application programs 435, other program modules 436 and program data 437.

The computer system 410 also includes a disk controller 440 coupled to the system bus 421 to control one or more storage devices for storing information and instructions, such as a magnetic hard disk 441 and a removable media drive 442 (e.g., floppy disk drive, compact disc drive, tape drive, and/or solid-state drive). Storage devices may be added to the computer system 410 using an appropriate device interface (e.g., a small computer system interface (SCSI), integrated device electronics (IDE), Universal Serial Bus (USB), or FireWire).

The computer system 410 may also include a display controller 465 coupled to the system bus 421 to control a display or monitor 466, such as a cathode ray tube (CRT) or liquid crystal display (LCD), for displaying information to a computer user. The computer system includes an input interface 460 and one or more input devices, such as a keyboard 462 and a pointing device 461, for interacting with a computer user and providing information to the processors 420. The pointing device 461, for example, may be a mouse, a light pen, a trackball, or a pointing stick for communicating direction information and command selections to the processors 420 and for controlling cursor movement on the display 466. The display 466 may provide a touch screen interface which allows input to supplement or replace the communication of direction information and command selections by the pointing device 461. In some embodiments, an augmented reality device 467 that is wearable by a user, may provide input/output functionality allowing a user to interact with both a physical and virtual world. The augmented reality device 467 is in communication with the display controller 465 and the user input interface 460 allowing a user to interact with virtual items generated in the augmented reality device 467 by the display controller 465. The user may also provide gestures that are detected by the augmented reality device 467 and transmitted to the user input interface 460 as input signals.

The computer system 410 may perform a portion or all of the processing steps of embodiments of the invention in response to the processors 420 executing one or more sequences of one or more instructions contained in a memory, such as the system memory 430. Such instructions may be read into the system memory 430 from another computer readable medium, such as a magnetic hard disk 441 or a removable media drive 442. The magnetic hard disk 441 may contain one or more datastores and data files used by embodiments of the present invention. Datastore contents and data files may be encrypted to improve security. The processors 420 may also be employed in a multi-processing arrangement to execute the one or more sequences of instructions contained in system memory 430. In alternative embodiments, hard-wired circuitry may be used in place of or in combination with software instructions. Thus, embodiments are not limited to any specific combination of hardware circuitry and software.

As stated above, the computer system 410 may include at least one computer readable medium or memory for holding instructions programmed according to embodiments of the invention and for containing data structures, tables, records, or other data described herein. The term “computer readable medium” as used herein refers to any medium that participates in providing instructions to the processors 420 for execution. A computer readable medium may take many forms including, but not limited to, non-transitory, non-volatile media, volatile media, and transmission media. Non-limiting examples of non-volatile media include optical disks, solid state drives, magnetic disks, and magneto-optical disks, such as magnetic hard disk 441 or removable media drive 442. Non-limiting examples of volatile media include dynamic memory, such as system memory 430. Non-limiting examples of transmission media include coaxial cables, copper wire, and fiber optics, including the wires that make up the system bus 421. Transmission media may also take the form of acoustic or light waves, such as those generated during radio wave and infrared data communications.

The computing environment 400 may further include the computer system 410 operating in a networked environment using logical connections to one or more remote computers, such as remote computing device 480. Remote computing device 480 may be a personal computer (laptop or desktop), a mobile device, a server, a router, a network PC, a peer device, or other common network node, and typically includes many or all of the elements described above relative to computer system 410. When used in a networking environment, computer system 410 may include modem 472 for establishing communications over a network 471, such as the Internet. Modem 472 may be connected to system bus 421 via user network interface 470, or via another appropriate mechanism.

Network 471 may be any network or system generally known in the art, including the Internet, an intranet, a local area network (LAN), a wide area network (WAN), a metropolitan area network (MAN), a direct connection or series of connections, a cellular telephone network, or any other network or medium capable of facilitating communication between computer system 410 and other computers (e.g., remote computing device 480). The network 471 may be wired, wireless or a combination thereof. Wired connections may be implemented using Ethernet, Universal Serial Bus (USB), RJ-6, or any other wired connection generally known in the art. Wireless connections may be implemented using Wi-Fi, WiMAX, and Bluetooth, infrared, cellular networks, satellite, or any other wireless connection methodology generally known in the art. Additionally, several networks may work alone or in communication with each other to facilitate communication in the network 471.

An executable application, as used herein, comprises code or machine-readable instructions for conditioning the processor to implement predetermined functions, such as those of an operating system, a context data acquisition system or other information processing system, for example, in response to user command or input. An executable procedure is a segment of code or machine-readable instruction, sub-routine, or other distinct section of code or portion of an executable application for performing one or more particular processes. These processes may include receiving input data and/or parameters, performing operations on received input data and/or performing functions in response to received input parameters, and providing resulting output data and/or parameters.

A graphical user interface (GUI), as used herein, comprises one or more display images, generated by a display processor and enabling user interaction with a processor or other device and associated data acquisition and processing functions. The GUI also includes an executable procedure or executable application. The executable procedure or executable application conditions the display processor to generate signals representing the GUI display images. These signals are supplied to a display device which displays the image for viewing by the user. The processor, under control of an executable procedure or executable application, manipulates the GUI display images in response to signals received from the input devices. In this way, the user may interact with the display image using the input devices, enabling user interaction with the processor or other device.

The functions and process steps herein may be performed automatically or wholly or partially in response to user command. An activity (including a step) performed automatically is performed in response to one or more executable instructions or device operation without user direct initiation of the activity.

The system and processes of the figures are not exclusive. Other systems, processes and menus may be derived in accordance with the principles of the invention to accomplish the same objectives. Although this invention has been described with reference to particular embodiments, it is to be understood that the embodiments and variations shown and described herein are for illustration purposes only. Modifications to the current design may be implemented by those skilled in the art, without departing from the scope of the invention. As described herein, the various systems, subsystems, agents, managers, and processes can be implemented using hardware components, software components, and/or combinations thereof.

What is claimed is:

1. A computer-implemented method of engineering design comprising:
for a design under test, performing a simulation (120) of the design interacting in a real-world environment;
in a computer processor, generating simulation data from performance of the simulation;
storing the generated simulation data in a computer memory (121);
extracting the generated simulation data to train a first inverse model neural network (122); and
generating a plurality of design parameters from the inverse model neural network (123).

2. The method of claim 1, further comprising:
generating a visualization (140) representative of the generated plurality of design parameters.

3. The method of claim 2, further comprising:
generating a scatter plot of the plurality of design parameters (123) for display to a user.

4. The method of claim 2, further comprising:
generating a 2D contour plot of the generated plurality of design parameters (123) for display to a user.

5. The method of claim 2, further comprising:
generating a parallel plot of the generated plurality of design parameters (123) for display to a user.

6. The method of claim 2, further comprising:
presenting the visualization (140) to a user; and
receiving a selection of one or more of the generated plurality of design parameters from the user based on the visualization (140).

7. The method of claim 6, further comprising:
performing a second simulation (110) using the selected one or more of plurality of design parameters (113) as input.

8. The method of claim 1, further comprising:
inserting represented knowledge (130) from a previously trained inverse model neural network (112) into the first inverse model neural network (120).

9. The method of claim 8, further comprising:
inserting the represented knowledge (140) from the previously trained inverse model neural network (112) by copying one or more layers of the previously trained inverse model neural network (112) including weights of the layers into the first inverse model neural network (122).

10. The method of claim 1, wherein the design under test is a design for an autonomous vehicle.

11. The method of claim 10, wherein the design parameters (123) are related to an advanced driver assistance system.

12. The method of claim 10, further comprising:
providing a safety metric as input to the inverse model neural network (122).

13. The method of claim 12, wherein the safety metric comprises a scenario characterization and an effect parameter.

14. The method of claim 12, further comprising:
generating the design parameters by sampling from a conditional distribution based on the safety metric.

15. The method of claim 14, further comprising:
applying a mixture density network (201) to approximate the conditional distribution of design parameters.

16. A system for exploring an engineering design space comprising:
a computer processor (420) in communication with a non-transitory computer memory (430), the non-transitory computer memory (430) storing instructions (435) that when executed by the computer processor cause the computer processor to:
for a design under test, perform a simulation (120) of the design interacting in a real-world environment;
generate simulation data from performance of the simulation (120);
store the generated simulation data in a computer memory (121);
extract the generated simulation data to train a first inverse model neural network (122); and
generate a plurality of design parameters (123) from the inverse model neural network.

17. The system of claim 16, the non-transitory computer memory (430) storing instructions that when executed by the computer processor (420), cause the computer processor to:
generate a visualization (140) representative of the generated plurality of design parameters (123).

18. The system of claim 16, the non-transitory computer memory (430) storing instructions that when executed by the computer processor (420), cause the computer processor to:
insert represented knowledge (140) from a previously trained inverse model neural network (112) into the first inverse model neural network (122).

19. The system of claim 16, the non-transitory computer memory (430) storing instructions that when executed by the computer processor (420), cause the computer processor to:
insert the represented knowledge (140) from the previously trained inverse model neural network by copying one or more layers of the previously trained inverse model neural network including weights of the layers into the first inverse model neural network.

20. The system of claim 16, wherein the design parameters (123) related to an advanced driver assistance system.
